(19) United States
(12) Patent Application Publication
(10) Pub. No.: US 2019/0259345 A1
(43) Pub. Date: Aug. 22, 2019

(54) DISPLAY PANEL

(71) Applicant: Sharp Kabushiki Kaisha, Sakai City (JP)

(72) Inventors: Kohei HOSOYACHI, Sakai City (JP); Takahiro YAMAGUCHI, Sakai City (JP); Shige FURUTA, Sakai City (JP); Nami NAGIRA, Sakai City (JP); Yuhichiroh MURAKAMI, Sakai City (JP)

(21) Appl. No.: 16/183,768

(22) Filed: Nov. 8, 2018

(30) Foreign Application Priority Data
Feb. 16, 2018 (JP) 2018-026451

(51) Int. Cl. G09G 3/36; H01L 27/12; G02F 1/1343; G02F 1/1335

(52) U.S. Cl. CPC G09G 3/3648; H01L 27/124; G02F 1/134309; G02F 2201/123; G02F 2201/56; G09G 2320/0233; G02F 2201/121; G02F 1/133514

(57) ABSTRACT

Luminance unevenness in a display area having an irregular shape is suppressed. An edge of the display area includes an irregularly-shaped edge which is curved. An end part of a signal switching circuit is located on an outer side of the irregularly-shaped edge. A driver is provided so as not to overlap with the end part of the signal switching circuit, as viewed in a first direction. An nth scanning signal line crosses the irregularly-shaped edge, passes through a space between the irregularly-shaped edge and the end part of the signal switching circuit, and is drawn to the driver, as viewed from above.

This Nonprovisional application claims priority under 35 U.S.C. § 119 on Patent Application No. 2018-026451 filed in Japan on Feb. 16, 2018, the entire contents of which are hereby incorporated by reference.

### TECHNICAL FIELD

The present invention relates to a display panel.

### BACKGROUND ART

Patent Literature 1 discloses a technique of suppressing luminance unevenness in a display area having an irregular shape (such a shape that corners are obliquely cut off).

### CITATION LIST

### Patent Literature

[Patent Literature 1] Japanese Patent Application Publication, Tokukai, No. 2012-103335 (published on May 31, 2012)

### SUMMARY OF INVENTION

### Technical Problem

According to the technique disclosed in Patent Literature 1, there is a problem that a shape of the display area is limited. In addition, there is a problem that adjustment of a data signal is needed.

### Solution to Problem

A display panel in accordance with an aspect of the present invention is a display panel including: a display area; sub pixels which are provided in the display area; a driver which is located on an outer side of an edge of the display area; a signal switching circuit which is located on the outer side of the edge of the display area; and an mth scanning signal line and an nth scanning signal line each of which extends in a first direction in the display area, the edge of the display area including an irregularly-shaped edge which is curved or oblique with respect to the first direction, an end part of the signal switching circuit being located on an outer side of the irregularly-shaped edge, the nth scanning signal line crossing the irregularly-shaped edge, passing through a space between the irregularly-shaped edge and the end part of the signal switching circuit, and being drawn to the driver, as viewed from above.

### Advantageous Effects of Invention

According to an aspect of the present invention, it is possible to suppress luminance unevenness in a display area which has an irregularly-shaped edge.

### BRIEF DESCRIPTION OF DRAWINGS

(a) of FIG. 1 is a schematic view illustrating a configuration of a display device in accordance with Embodiment 1. (b) of FIG. 1 is a cross-sectional view illustrating the configuration of the display device. (c) of FIG. 1 is a circuit diagram illustrating a sub pixel.

FIG. 2 is a plan view illustrating a configuration of a vicinity of an edge, having an irregular shape, in Embodiment 1.

(a) of FIG. 3 is a plan view illustrating a configuration of a unit circuit (switching circuit) included in a signal switching circuit. (b) of FIG. 3 is a cross-sectional view illustrating a configuration of a pixel, viewed along arrows in (a) of FIG. 3.

(a) of FIG. 4 is a schematic view illustrating a configuration of a gate driver (GD1). (b) of FIG. 4 is a timing chart illustrating operation of the gate driver.

(a) of FIG. 5 is a schematic view illustrating a configuration of another gate driver (GD2). (b) of FIG. 5 is a timing chart illustrating operation of the another gate driver.

FIG. 6 is a waveform chart illustrating an effect of Embodiment 1.

(a) of FIG. 7 is a plan view illustrating Comparative Example. (b) of FIG. 7 is a waveform chart concerning Comparative Example.

FIG. 8 is a plan view illustrating variations of Embodiment 1.

FIG. 9 is a plan view illustrating a variation of Embodiment 1.

FIG. 10 is a plan view illustrating a variation of Embodiment 1.

FIG. 11 is a plan view illustrating a configuration of a liquid crystal panel in accordance with Embodiment 2.

FIG. 12 is a plan view illustrating a configuration of a liquid crystal panel in accordance with Embodiment 3.

FIG. 13 is a plan view illustrating a variation of Embodiment 3.

FIG. 14 is a plan view illustrating a configuration of a liquid crystal panel in accordance with Embodiment 4.

FIG. 15 is a plan view illustrating a configuration of a liquid crystal panel in accordance with Embodiment 5.

(a) of FIG. 16 is a circuit diagram illustrating a configuration of an analog switch of a unit circuit. (b) of FIG. 16 is a timing chart illustrating a waveform of an electric potential of a control wire and waveforms of electric potentials of data signal lines.

FIG. 17 is a plan view illustrating a configuration of a liquid crystal panel in accordance with Embodiment 6.

FIG. 18 is a plan view illustrating a variation of Embodiment 6.

### DESCRIPTION OF EMBODIMENTS

(a) of FIG. 1 is a schematic view illustrating a configuration of a display device in accordance with Embodiment 1. (b) of FIG. 1 is a cross-sectional view illustrating the configuration of the display device. (c) of FIG. 1 is a circuit diagram illustrating a sub pixel. As illustrated in FIG. 1, a display device 2 includes a backlight unit BU, a liquid crystal panel LP (display panel), a source driver SD, and a display control circuit DCC. A gate driver GD1, a gate driver GD2, and a signal switching circuit SK are monolithically provided to the liquid crystal panel LP. The display control circuit DCC controls the source driver SD, the gate driver GD1, and the gate driver GD2. The signal switching circuit SK is a circuit for writing grayscale signals (analog electric potential) for R (red), G (green), and B (blue) in a time division manner, and is connected to the source driver SD.

The liquid crystal panel LP includes (i) an active matrix substrate 3 which includes data signal lines including a data signal line DLx and a data signal line DLz, scanning signal lines including a scanning signal line Gm and a scanning signal line Gn, the gate driver GD1, and the gate driver GD2, (ii) a liquid crystal layer 4, (iii) a color filter substrate 5 which includes a color filter, and (iv) a functional layer 6 which includes an optical film and touch panel.

The liquid crystal panel LP is an irregularly-shaped panel having four round corners. An edge of a display area DA in which a plurality of sub pixels (SPm, SPn, SPM, SPN) are provided includes (i) a straight edge TE, (ii) an irregularly-shaped edge RE (round corner edge) which has an arc shape and which leads to the straight edge TE, (iii) a straight edge Te, and (iv) an irregularly-shaped edge Re which has an arc shape and which leads to the straight edge Te.

A sub pixel SPi (i=m, n, M, N) includes a transistor TR and a pixel electrode PE. The sub pixel SPi is connected to (i) a scanning signal line Gi (i=m, n) and (ii) a data signal line DLx/DLz. Specifically, the pixel electrode PE is connected to the data signal line DLx/DLz via the transistor TR, and a gate electrode of the transistor TR is connected to the scanning signal line Gi. A liquid crystal capacitance Clc is formed between the pixel electrode PE and a common electrode com, and a storage capacitance Ccs is formed between the pixel electrode PE and a storage capacitor wiring CSi. Note that the storage capacitor wiring CSi is provided to the active matrix substrate 3, and the common electrode com is provided to the active matrix substrate 3 or the color filter substrate 5. An oxide semiconductor (for example, an In—Ga—Zn—O-based semiconductor), low-temperature polysilicon (LTPS), amorphous silicon, or the like can be used for a channel of the transistor TR.

### Embodiment 1

In FIG. 1, the gate driver GD1, the gate driver GD2, and the signal switching circuit SK are provided in a non-display area NA (a frame in which no sub pixel is provided) which surrounds the display area DA (in which the plurality of sub pixels are provided and in which an image can be displayed). The signal switching circuit SK extends in a first direction D1 in a lateral side (short side) of the frame. One end part SKZ of the signal switching circuit SK is located on an outer side of the irregularly-shaped edge RE, and the other end part SKz of the signal switching circuit SK is located on an outer side of the irregularly-shaped edge Re. The gate driver GD1 extends in a second direction D2 (direction perpendicular to the first direction D1) in one vertical side (long side) of the frame, and is located on an outer side of the straight edge TE. Similarly, the gate driver GD2 extends in the second direction D2 in the other vertical side (long side) of the frame, and is located on an outer side of the straight edge Te.

The scanning signal line Gm extends in the first direction D1 in the display area DA. One end of the scanning signal line Gm crosses the straight edge TE and is connected to the gate driver GD1, and the other end of the scanning signal line Gm crosses the straight edge Te and is connected to the gate driver GD2. The scanning signal line Gn extends in the first direction D1 in the display area DA. One end of the scanning signal line Gn crosses the irregularly-shaped edge RE and is connected to the gate driver GD1, and the other end of the scanning signal line Gn crosses the irregularly-shaped edge Re and is connected to the gate driver GD2.

The number of sub pixels which are connected to the scanning signal line Gn is less than the number of sub pixels which are connected to the scanning signal line Gm. Therefore, as viewed from each of the gate drivers GD1 and GD2, the scanning signal line Gn is a low-load scanning signal line as compared with the scanning signal line Gm.

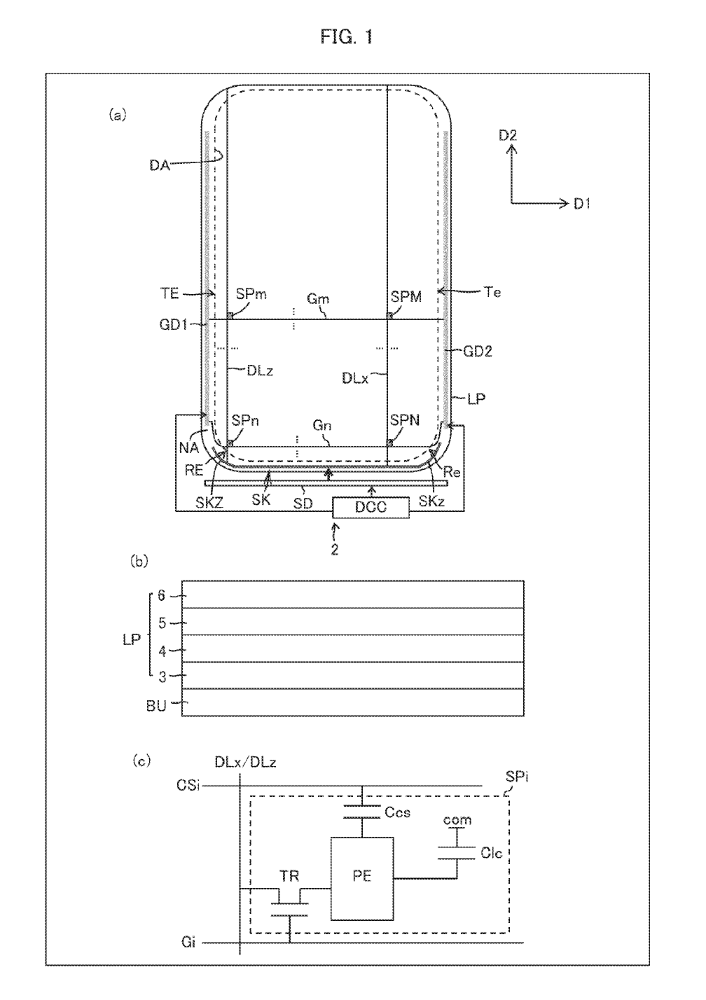

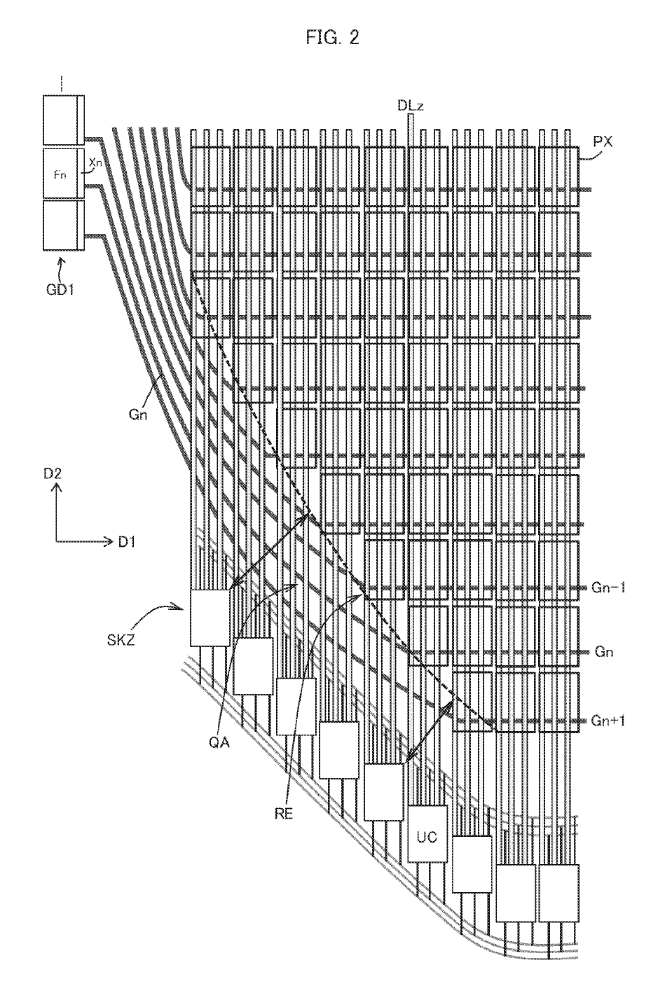

FIG. 2 is a plan view illustrating a configuration of a vicinity of an irregularly-shaped edge in Embodiment 1. (a) of FIG. 3 is a plan view illustrating a configuration of a unit circuit (switching circuit) included in a signal switching circuit. (b) of FIG. 3 is a cross-sectional view illustrating a configuration of a pixel, viewed along arrows in (a) of FIG. 3.

As illustrated in FIGS. 1 and 2, the one end part SKZ of the signal switching circuit SK is curved (rounded) as with the irregularly-shaped edge RE, and the gate driver GD1 is provided so as not to overlap with the one end part SKZ of the signal switching circuit SK as viewed in the first direction D1. Similarly, the other end part SKz of the signal switching circuit SK is curved (rounded) as with the irregularly-shaped edge Re, and the gate driver GD2 is provided so as not to overlap with the other end part SKz of the signal switching circuit SK as viewed in the first direction D1.

As viewed from above, the one end of the scanning signal line Gn crosses the irregularly-shaped edge RE, passes through a space QA between the irregularly-shaped edge RE and the one end part SKZ of the signal switching circuit SK, and is drawn to the gate driver GD1. Meanwhile, as viewed from above, the other end of the scanning signal line Gn crosses the irregularly-shaped edge Re, passes through a space between the irregularly-shaped edge Re and the other end part SKz of the signal switching circuit SK, and is drawn to the gate driver GD2.

As illustrated in FIG. 2 and (a) of FIG. 3, the signal switching circuit SK is constituted by a plurality of unit circuits UC. A unit circuit UC is configured such that three CMOS analog switches, each of which includes an n-channel transistor Ta and a p-channel transistor Tb, are arranged side by side. The unit circuit UC is connected to six control wires. For example, an input end of an analog switch AS is connected to an analog input wire Iw, an output end of the analog switch AS is connected to a data signal line DLz(R), and two control ends of the analog switch AS (respective gate terminals of the transistors Ta and Tb) are connected to respective control wires CWR and CWr.

For example, while the analog switch AS is in an ON state (for example, a time period corresponding to ⅓ of 1 horizontal scanning period), the other two analog switches are each in an OFF state, and a grayscale signal (analog electric potential) for R (red) is supplied from the analog input wire Iw to a sub pixel SPn, corresponding to red, through the data signal line DLz(R). By thus providing the signal switching circuit SK for time division, it is possible to reduce the number of analog input wires Iw to ⅓. Note that sub pixels corresponding to respective three colors (red, green, and blue) constitute a pixel PX illustrated in FIG. 2.

As illustrated in (b) of FIG. 3, the active matrix substrate 3 illustrated in FIG. 1 is configured such that the following members are provided on a substrate 10: (i) semiconductor films SC; (ii) an inorganic insulating film 14 which is provided in a layer higher than a layer in which the semiconductor films SC are provided; (iii) gate electrodes GE which are provided in a layer higher than the layer in which the inorganic insulating film 14 is provided; (iv) an inorganic insulating film 16 which is provided in a layer higher than the layer in which the gate electrodes GE are provided; (v) the data signal lines, including the data signal line DLz(R), which are provided in a layer higher than the layer in which the inorganic insulating film 16 is provided; (vi) an inorganic insulating film 18 which is provided in a layer higher than the layer in which the data signal lines are provided; (vii) an organic insulating film 20 which is provided in a layer higher than the layer in which the inorganic insulating film 18 is provided; (viii) pixel electrodes PE which are provided in a layer higher than the layer in which the organic insulating film 20 is provided; (ix) an inorganic insulating film 21 which is provided in a layer higher than the layer in which the pixel electrodes PE are provided; (x) the common electrode com which is provided in a layer higher than the layer in which the inorganic insulating film 21 is provided; (xi) an inorganic insulating film 22 which is provided in a layer higher than the layer in which the common electrode com is provided; and (xii) an alignment film (not illustrated) which is provided in a layer higher than the layer in which the inorganic insulating film 22 is provided.

Silicon nitride or silicon oxide can be, for example, used for the inorganic insulating films 14, 16, 18, 21, and 22. Meanwhile, an applicable photosensitive organic material, such as polyimide or acrylic, can be, for example, used for the organic insulating film (planarizing film) 20. A light transmissive conductive film, such as ITO or IZO, can be used for the pixel electrodes PE and the common electrode com. Aluminum (Al), tungsten (W), molybdenum (Mo), tantalum (Ta), chrome (Cr), titanium (Ti), or copper (Cu) can be, for example, used for the gate electrodes GE and the data signal lines including the data signal lines DLx and DLz.

Transistors TR are each constituted by a corresponding one of the gate electrodes GE and a corresponding one of the semiconductor films SC. For example, a gate electrode GE is connected to the scanning signal line Gn, which is provided in the layer in which the gate electrode GE is provided. A source region (low-resistance region) of a semiconductor film SC is connected to the data signal line DLx/DLz via a contact hole, and a drain region (low-resistance region) of the semiconductor film SC is connected to a pixel electrode PE of a sub pixel SPn via a contact hole. Note that orientation in the liquid crystal layer 4 (FIG. 1) is controlled by a transverse electric field generated between the pixel electrodes PE and the common electrode com.

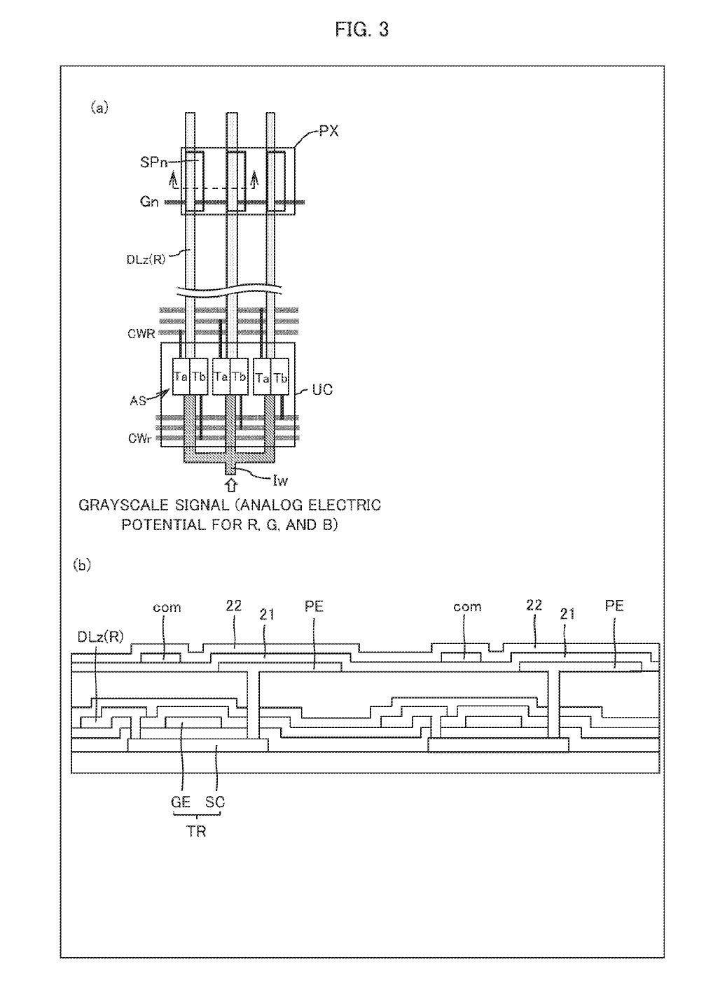

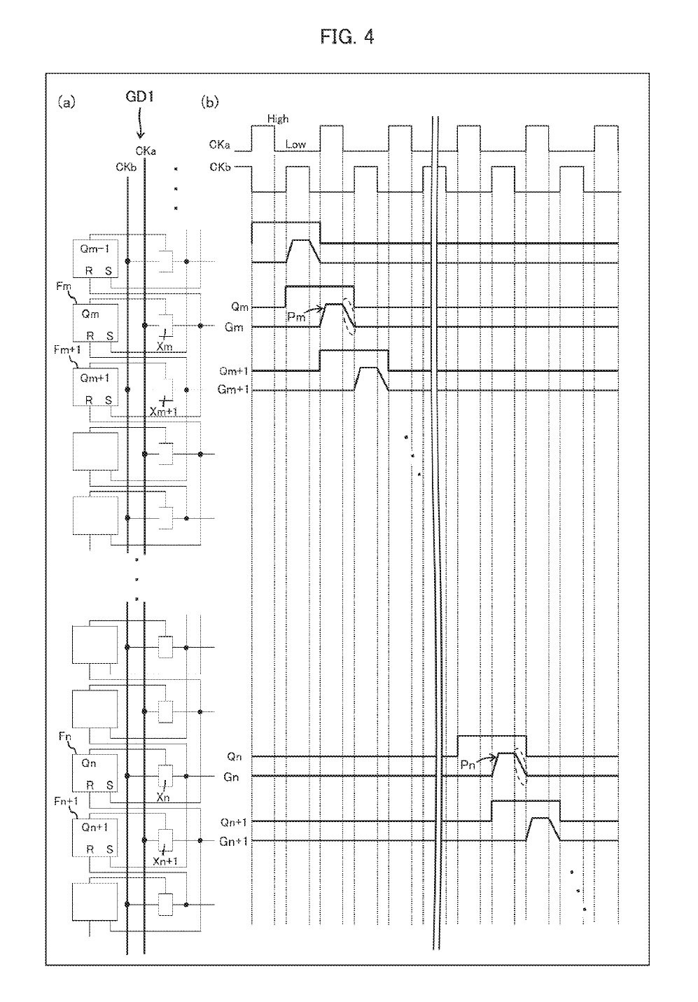

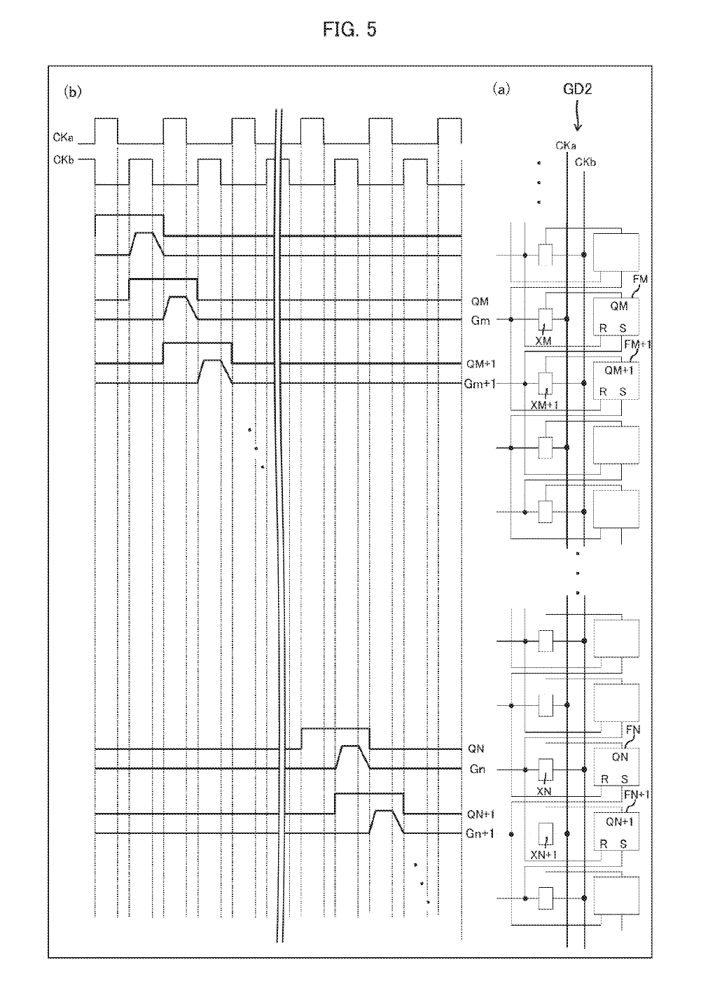

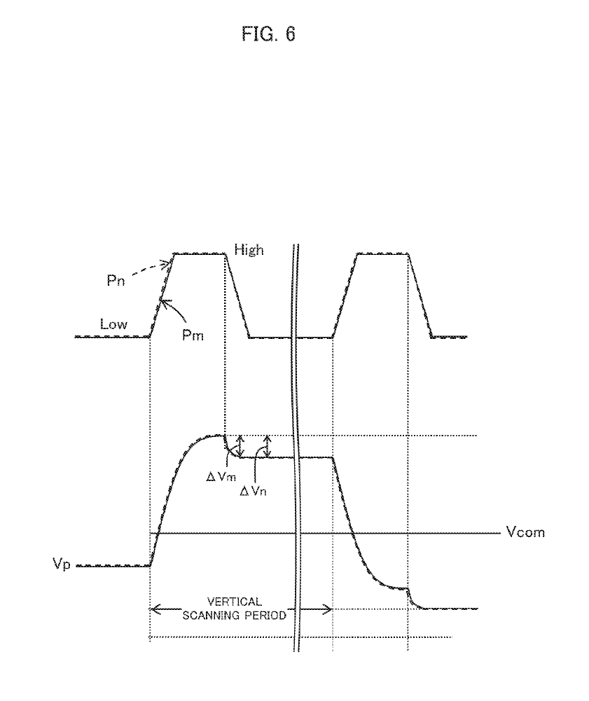

(a) of FIG. 4 is a schematic view illustrating a configuration of a gate driver (GD1). (b) of FIG. 4 is a timing chart illustrating operation of the gate driver (GD1). (a) of FIG. 5 is a schematic view illustrating a configuration of another gate driver (GD2). (b) of FIG. 5 is a timing chart illustrating operation of the another gate driver (GD2). FIG. 6 is a waveform chart illustrating an effect of Embodiment 1. (a) of FIG. 7 is a plan view illustrating Comparative Example. (b) of FIG. 7 is a waveform chart concerning Comparative Example.

As illustrated in FIGS. 4 and 5, the gate driver GD1 includes a plurality of flip flops and a plurality of output circuits. An output circuit Xm connected to an mth flip flop Fm is connected to the scanning signal line Gm. An output circuit Xn connected to an nth flip flop Fn is connected to the scanning signal line Gn.

The gate driver GD2 includes a plurality of flip flops and a plurality of output circuits. An output circuit XM connected to an mth flip flop FM is connected to the scanning signal line Gm. An output circuit XN connected to an nth flip flop FN is connected to the scanning signal line Gn.

According to Embodiment 1, the scanning signal line Gn, which is a low-load scanning signal line (a load imposed during driving of sub pixels is low) as compared with the scanning signal line Gm, is provided in the following manner. That is, the one end of the scanning signal line Gn is drawn to the output circuit Xn of the gate driver GD1 so as to pass through the space QA between the irregularly-shaped edge RE and the one end part SKZ of the signal switching circuit SK, and the other end of the scanning signal line Gn is drawn to the output circuit XN of the gate driver GD2 so as to pass through the space between the irregularly-shaped edge Re and the other end part SKz of the signal switching circuit SK, as viewed from above. By thus making a length (total length of part passing through the display area DA and part passing through the non-display area NA) of the scanning signal line Gn, which is a low-load scanning signal line, shorter than a length (total length of part passing through the display area DA and part passing through the non-display area NA) of the scanning signal line Gm, which is a high-load scanning signal line (that is, by adding greater wiring resistance to the scanning signal line Gn), it is possible to cause a time constant of the scanning signal line Gn to match a time constant of the scanning signal line Gm, and possible to cause a returning edge (falling edge enclosed by a broken line in FIG. 4) of a scanning pulse Pn, which is outputted from each of the output circuits Xn and XN to the scanning signal line Gn, to match a returning edge of a scanning pulse Pm, which is outputted from each of the output circuits Xm and XM to the scanning signal line Gm, as illustrated in (b) of FIG. 4, (b) of FIG. 5, and FIG. 6. This allows a reduction in luminance unevenness between (i) a region between the irregularly-shaped edges RE and Re and (ii) a region between the straight edges TE and Te.

As illustrated in FIG. 6, with regard to the scanning signal line Gm, a voltage Vp of each pixel electrode PE is pulled in a negative direction by ΔVm at a timing at which the scanning pulse Pm returns (falls), and, with regard to the scanning signal line Gn, a voltage Vp of each pixel electrode PE is pulled in the negative direction by ΔVn at a timing at which the scanning pulse Pn returns (falls). Such a feed-through voltage ΔVm and a feed-through voltage ΔVn each result from a capacitance Cgd (a parasitic capacitance between the scanning signal line and the pixel electrode). A suitable value of a voltage Vcom of the common electrode is dependent on the feed-through voltage ΔVm and the feed-through voltage ΔVn. The feed-through voltage ΔVm is dependent on the returning edge of the scanning pulse Pm, and the feed-through voltage ΔVn is dependent on the returning edge of the scanning pulse Pn. Therefore, by causing the returning edge of the scanning pulse Pm and the returning edge of the scanning pulse Pn to match each other, the suitable value of the voltage Vcom for the region between the irregularly-shaped edges RE and Re and the suitable value of the voltage Vcom for the region between the straight edges TE and Te are caused to match each other. This suppresses luminance unevenness.

Note that, according to Comparative Example in which a straight signal switching circuit sk is provided and a length of a scanning signal line GM which extends across straight edges is identical to a length of a scanning signal line GN which extends across irregularly-shaped edges ((a) of FIG. 7), a scanning pulse pn outputted to the scanning signal line GN returns (drops) more steeply than a scanning pulse Pm outputted to the scanning signal line GM, so that ΔVn becomes greater than ΔVm. This causes the suitable value of the voltage Vcom for a region between the irregularly-shaped edges to shift in the negative direction from the suitable value of the voltage Vcom for a region between the straight edges (see (b) of FIG. 7), and may cause luminance unevenness or image sticking (decrease in reliability). Furthermore, there is a problem that, since each of gate drivers gd1 and gd2 becomes longer, a frame (non-display area) becomes wider.

Note that a shift of the suitable value of the voltage Vcom can be adjusted by adjusting a grayscale signal to be written in each pixel electrode PE. However, in this case, it is disadvantageously necessary to customize the source driver SD. According to Embodiment 1, by drawing of the scanning signal line Gn of the active matrix substrate 3, there is an advantage that it is possible to deal with luminance unevenness.

Furthermore, according to the configuration in Embodiment 1, which configuration is illustrated in FIGS. 1 and 2, the number of connected sub pixels becomes less in order of a scanning signal line Gn−1, the scanning signal line Gn, and a scanning signal line Gn+1 (toward the signal switching circuit SK), and the scanning signal line Gn−1, the scanning signal line Gn, and the scanning signal line Gn+1 become accordingly longer in this order. Therefore, loads are equalized also in a lower end region sandwiched between the irregularly-shaped edges RE and Re. This makes it difficult for luminance unevenness to occur.

In FIG. 2, the one end part SKZ of the signal switching circuit SK is shaped so that a distance between the one end part SKZ and the irregularly-shaped edge RE becomes longer toward a tip of the signal switching circuit SK. Therefore, it is convenient to drawn a plurality of scanning signal lines in the space QA between the irregularly-shaped edge RE and the one end part SKZ of the signal switching circuit SK.

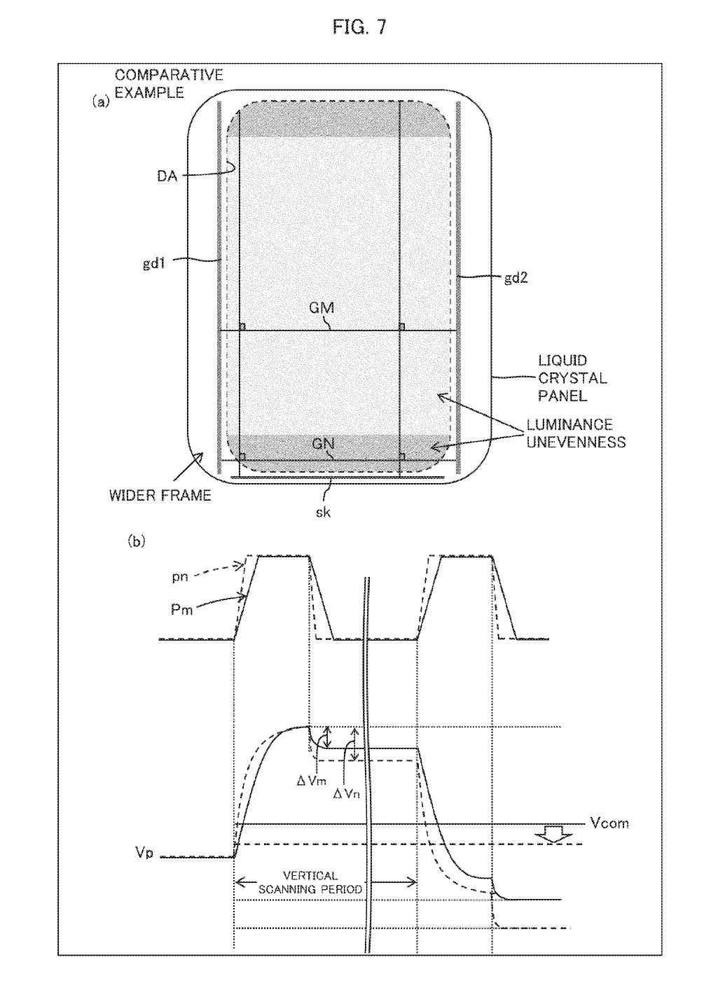

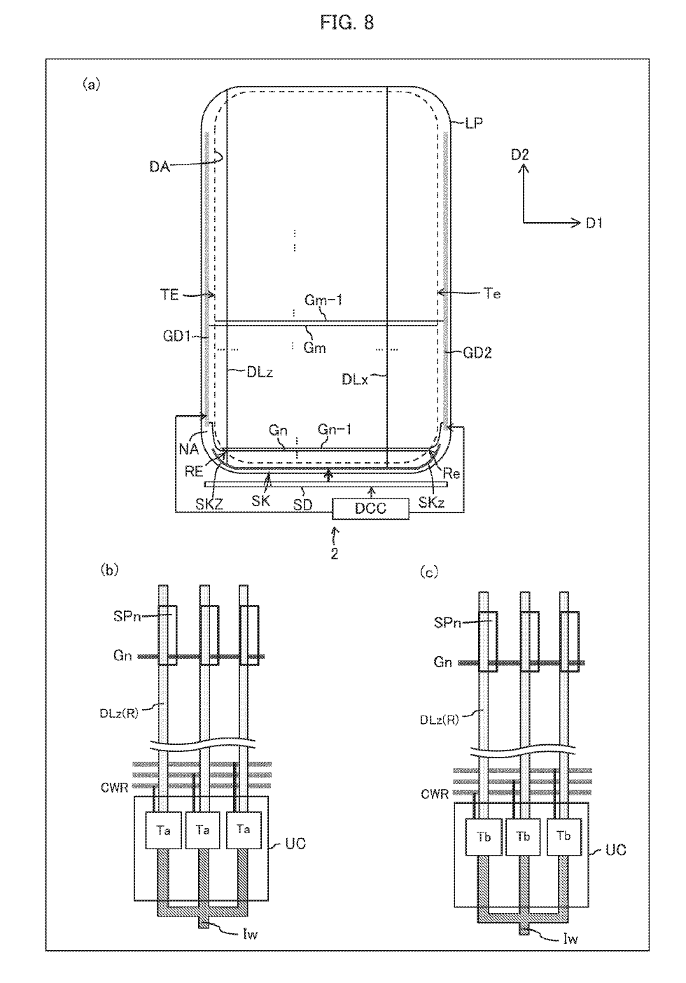

FIG. 8 is a schematic view illustrating variations of Embodiment 1. According to FIG. 1, each of the scanning signal line Gm and the scanning signal line Gn is connected to the gate driver GD1 and the gate driver GD2. However, the display device 2 is not limited to such a configuration. Alternatively, the display device 2 can be configured such that, for example, the scanning signal line Gn, which is an odd-numbered scanning signal line, is connected merely to the gate driver GD1 and the scanning signal line Gn+1, which is an even-numbered scanning signal line, is connected merely to the gate driver GD2 (see (a) of FIG. 8). Furthermore, in FIG. 3, the unit circuit UC is constituted by the CMOS analog switches, each of which is constituted by the n-channel transistor and the p-channel transistor. However, the display device 2 is not limited to such a configuration. Alternatively, the display device 2 can be configured such that the unit circuit UC is constituted by switches each of which is constituted by n-channel transistor Ta (see (b) of FIG. 8) or by p-channel transistor Tb (see (c) of FIG. 8).

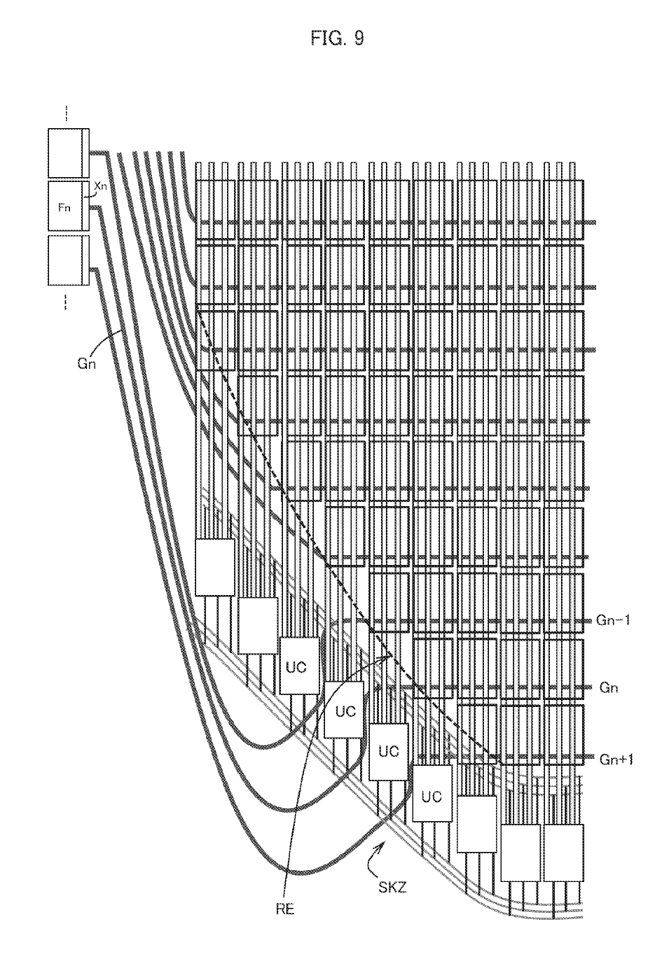

FIG. 9 is a plan view illustrating a variation of Embodiment 1. As illustrated in FIG. 9, the display device 2 can be configured such that the scanning signal line Gn is drawn so as to cross the one end part SKZ of the signal switching circuit SK (for example, pass through a space between adjacent unit circuits). This allows the space QA between the irregularly-shaped edge RE and the one end part SKZ of the signal switching circuit SK to be narrow, thereby increasing a degree of freedom of a panel layout.

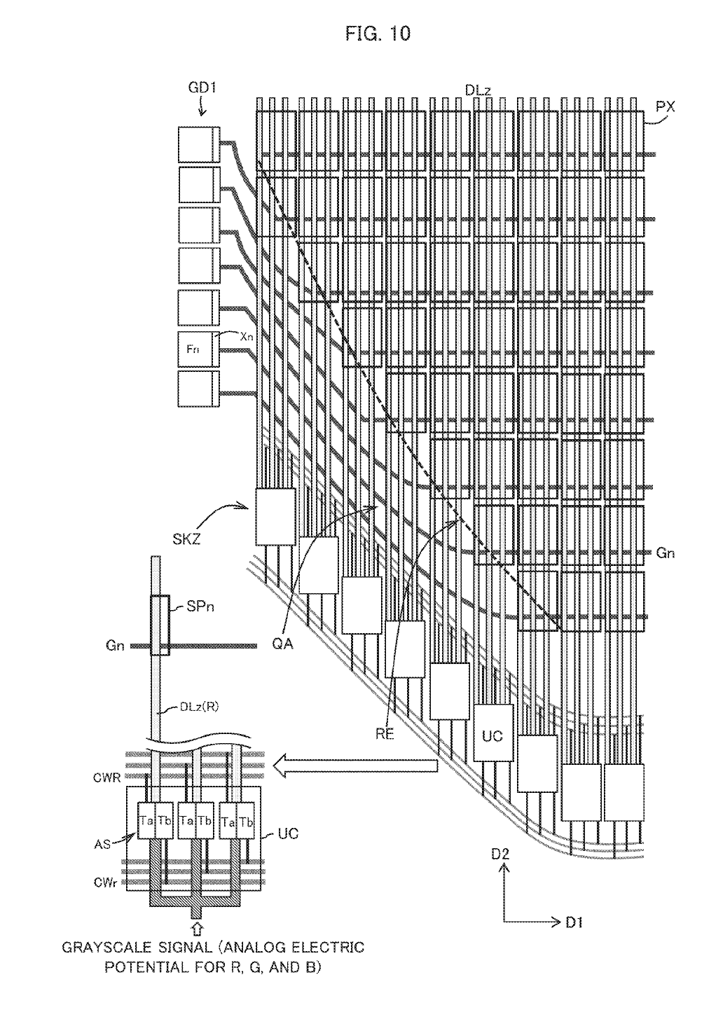

FIG. 10 is a plan view illustrating a further variation of Embodiment 1. According to FIGS. 1 and 2, the gate drivers GD1 and GD2 are provided so as not to overlap with the irregularly-shaped edges RE and Re, as viewed in the first direction D1. However, the display device 2 is not limited to such a configuration. Alternatively, as illustrated in FIG. 10, the gate driver GD1 can be provided so that an end part of the gate driver GD1 overlaps with the irregularly-shaped edge RE, as viewed in the first direction D1 (the gate driver GD2 can be provided similarly). This increases a degree of freedom of a panel layout. Furthermore, it is possible to reduce a size of the frame.

### Embodiment 2

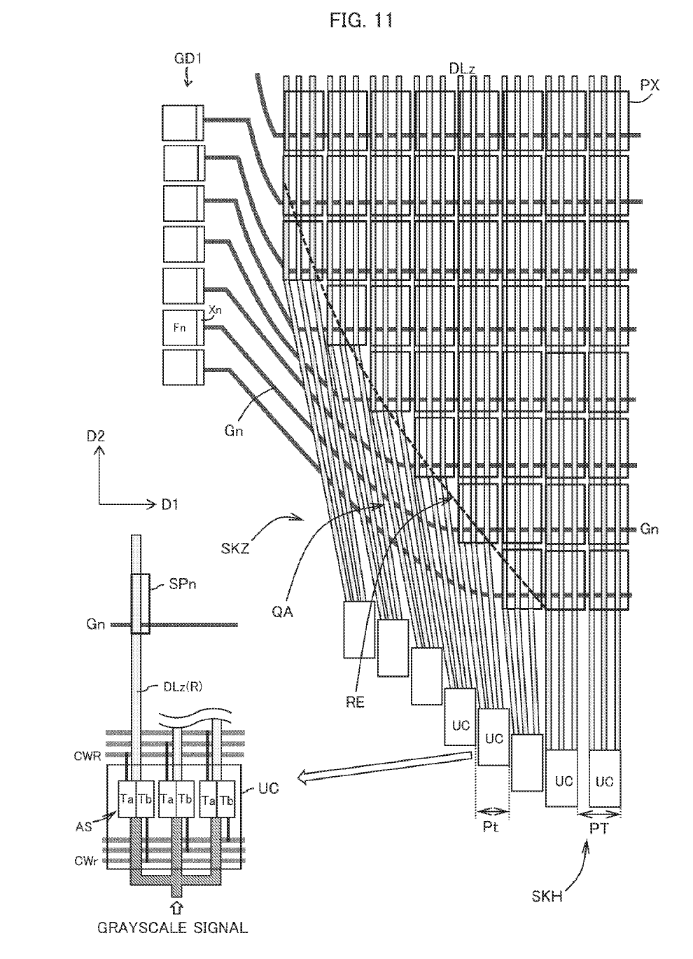

FIG. 11 is a plan view illustrating a configuration of a liquid crystal panel in accordance with Embodiment 2. In FIG. 11, control wires which are connected to one end part SKZ of a signal switching circuit SK are omitted. As illustrated in FIG. 11, a pitch Pt between adjacent unit circuits UC in each of the one end part SKZ and the other end part SKz (parts extending along respective irregularly-shaped edges RE and Re) of the signal switching circuit SK can be shorter than a pitch PT between adjacent unit circuits UC in a non-end part SKH (part parallel to a first direction D1) of the signal switching circuit SK. This allows a reduction in size of a non-display area NA (frame), and allows an increase in degree of freedom of a panel layout.

### Embodiment 3

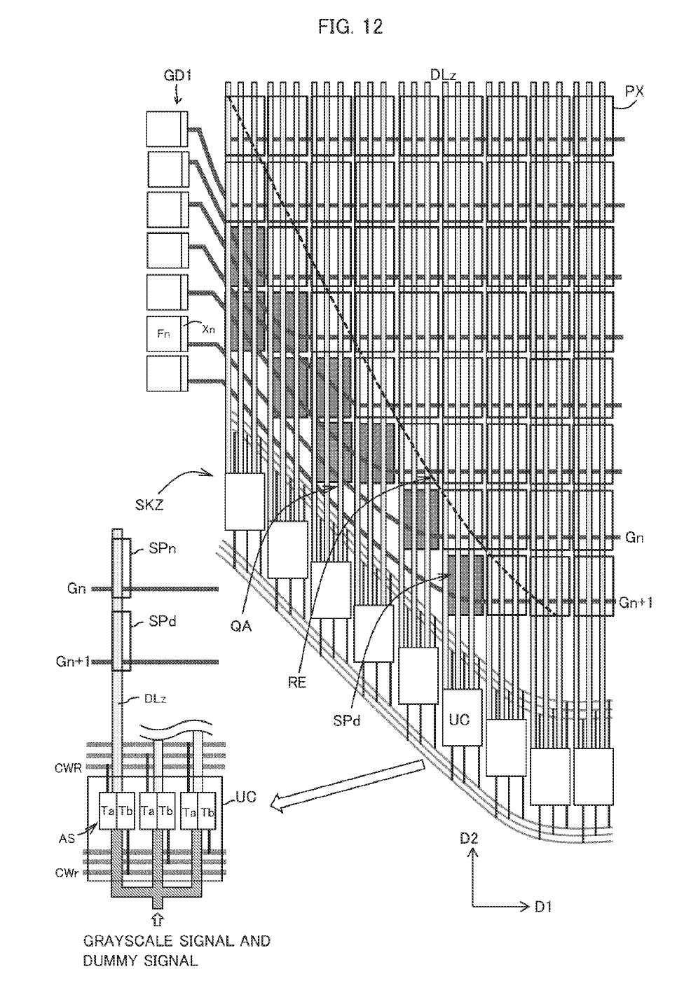

FIG. 12 is a plan view illustrating a configuration of a liquid crystal panel in accordance with Embodiment 3. As illustrated in FIG. 12, a dummy sub pixel SPd can be provided which is at least partially located on an outer side of an irregularly-shaped edge RE and which does not contribute to display (for example, a sub pixel to which a black color filter corresponds). The dummy sub pixel SPd can be connected to a scanning signal line Gn, which extends across the irregularly-shaped edge RE, and a data signal line DLz, which extends across the irregularly-shaped edge RE. This makes it possible to add a load of the dummy sub pixel SPd to each of the scanning signal line Gn, which is a low-load scanning signal line, and the data signal line DLz, which is a low-load data signal line. It is therefore possible to suppress each of horizontally striped luminance unevenness (see FIG. 7) and vertically striped luminance unevenness (luminance unevenness which occurs between a right end part, including round corners, of a display area, a left end part, including round corners, of the display area, and a middle part, sandwiched between the right end part and the left end part, of the display area). Note that a dummy signal is supplied to the dummy sub pixel SPd.

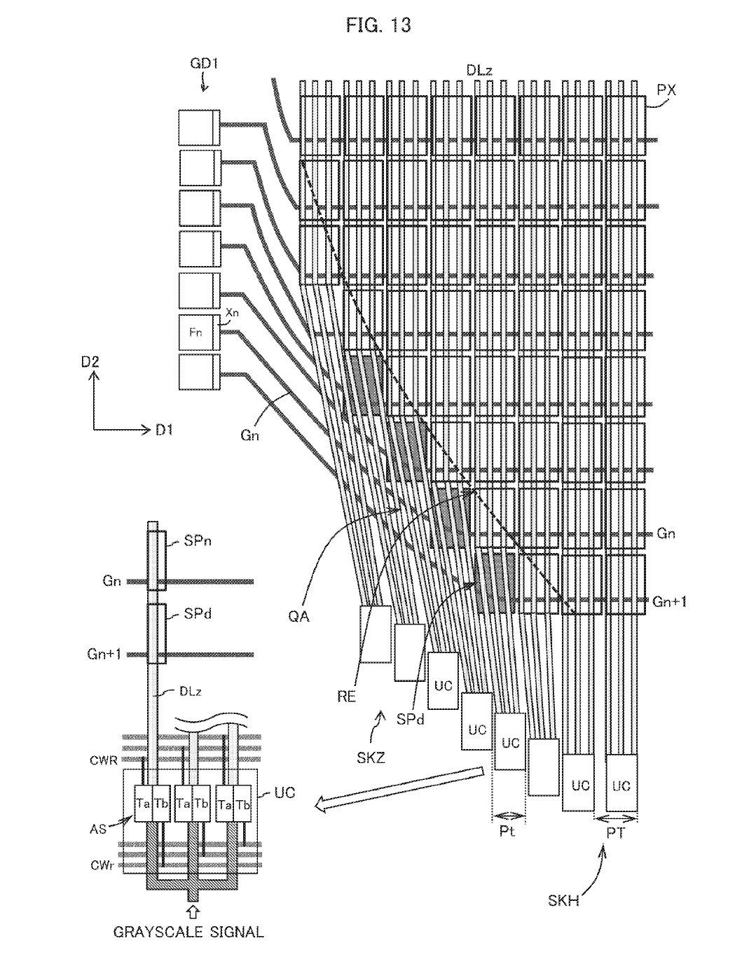

FIG. 13 is a plan view illustrating a variation of Embodiment 3. In FIG. 13, control wires which are connected to one end part SKZ of a signal switching circuit SK are omitted. As illustrated in FIG. 13, while a dummy sub pixel SPd is provided, a pitch Pt between adjacent unit circuits UC in each of the one end part SKZ and the other end part SKz (parts extending along respective irregularly-shaped edges RE and Re) of the signal switching circuit SK can be shorter than a pitch PT between adjacent unit circuits UC in a non-end part SKH (part parallel to a first direction D1) of the signal switching circuit SK.

### Embodiment 4

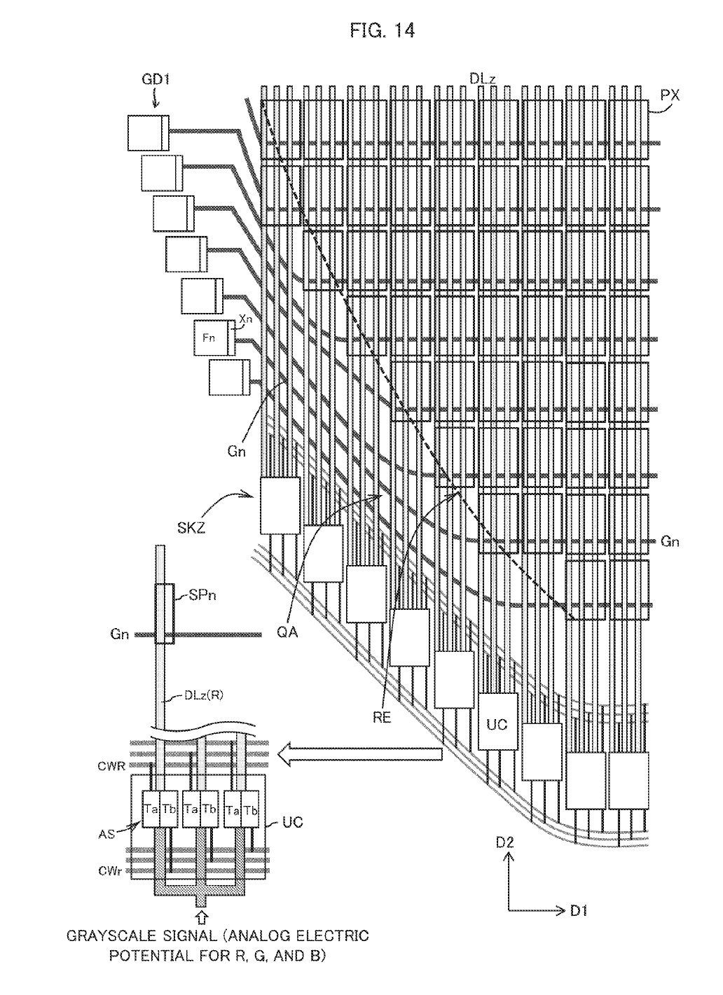

FIG. 14 is a plan view illustrating a configuration of a liquid crystal panel in accordance with Embodiment 4. As illustrated in FIG. 14, an end part of a gate driver GD1 can be curved so as to extend along an irregularly-shaped edge RE. This allows a reduction in size of a frame, and allows an increase in degree of freedom of a panel layout.

### Embodiment 5

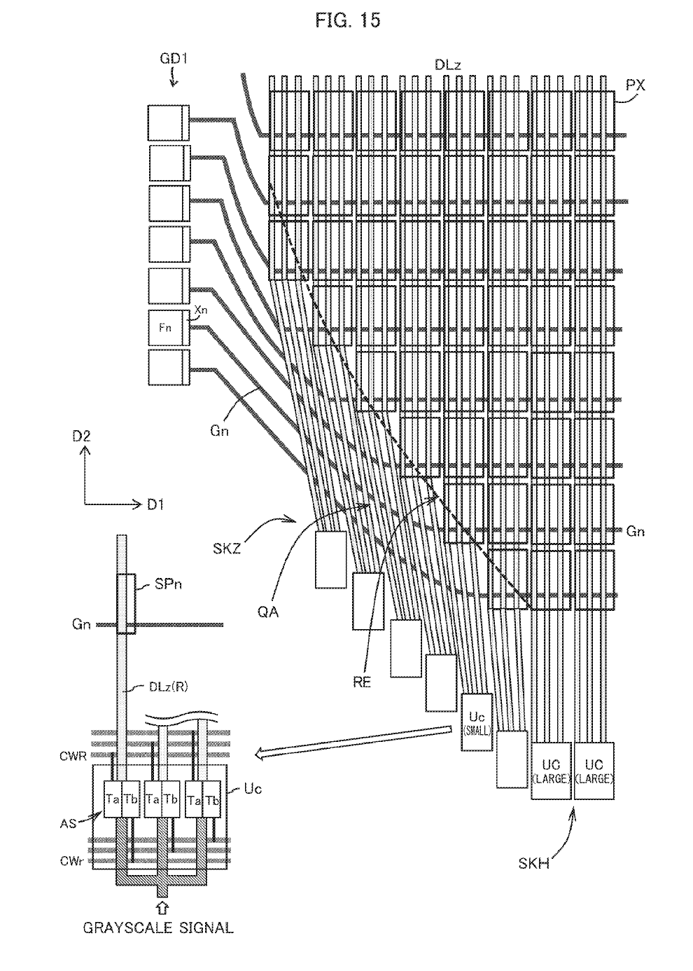

FIG. 15 is a plan view illustrating a configuration of a liquid crystal panel in accordance with Embodiment 5. In FIG. 15, control wires which are connected to one end part SKZ of a signal switching circuit SK are omitted. As illustrated in FIG. 15, each of unit circuits Uc included in each of one end part SKZ and the other end part SKz of the signal switching circuit SK can be smaller, in size, than each of unit circuits UC included in a non-end part SKH of the signal switching circuit SK. This allows a reduction in size of a frame, and allows an increase in degree of freedom of an outer shape of a panel.

Furthermore, a data signal line DLz which extends across an irregularly-shaped edge RE is a low-load data signal line as compared with a data signal line DLx which extends across a straight edge parallel to a first direction D1 (see FIG. 1) (the number of sub pixels connected to the data signal line DLz is less than the number of sub pixels connected to the data signal line DLx). Therefore, it is desirable that a driving capability of each of analog switches of a unit circuit Uc connected to the data signal line DLz be lower than that of each of analog switches of a unit circuit UC connected to the data signal line DLx. For example, by causing transistors Ta and transistors Tb included in the unit circuit Uc to be smaller, in size, than transistors Ta and transistors Tb included in the unit circuit UC, it is possible to suppress vertically striped luminance unevenness (luminance unevenness which can occur between a right end part, including round corners, of a display area, a left end part, including round corners, of the display area, and a middle part, sandwiched between the right end part and the left end part, of the display area).

In a case where the driving capability of each of the analog switches of the unit circuit Uc connected to the data signal line DLz is equal to that of each of the analog switches of the unit circuit UC connected to the data signal line DLx, a source waveform (waveform of an electric potential of a data signal line) with an identical grayscale and an identical polarity differs between the data signal line DLx and the data signal line DLz due to a difference between a load on the data signal line DLx and a load on the data signal line DLz (the source waveform of the data signal line DLz is more steeply changed). In view of the above, by causing the driving capability of each of the analog switches of the unit circuit Uc connected to the data signal line DLz to be lower than that of each of the analog switches of the unit circuit UC connected to the data signal line DLx, it is possible to cause distortion (degree of steepness) of the waveform of the electric potential of the data signal line DLx to match distortion of the waveform of the electric potential of the data signal line DLz.

(a) of FIG. 16 is a circuit diagram illustrating a configuration of an analog switch of a unit circuit UC. (b) of FIG. 16 is a timing chart illustrating a waveform of an electric potential of a control wire and waveforms of electric potentials of data signal lines. The vertically striped luminance unevenness as described above can also occur in case where a ratio (capacitance ratio) between a wiring capacitance Cpx of the data signal line DLx (see FIG. 1) and a parasitic capacitance of an analog switch connected to the data signal line DLx (a parasitic capacitance Ca between a gate and a source of a transistor Ta and a parasitic capacitance Cb between a gate and a source of a transistor Tb) differs from a ratio (capacitance ratio) between a wiring capacitance Cpz of the data signal line DLz and a parasitic capacitance of an analog switch connected to the data signal line DLz (a parasitic capacitance Ca between a gate and a source of a transistor Ta and a parasitic capacitance Cb between a gate and a source of a transistor Tb). This is because a change in electric potential of each of the data signal lines DLx and DLz, which change occurs at a timing at which each of pulse signals Ks and KBs of control wires returns (a switch is turned off), varies depending on the capacitance ratio. In consideration of Cpx>Cpz, by causing the parasitic capacitance of the analog switch of the unit circuit UC connected to the data signal line DLz to be lower than that of the analog switch of the unit circuit UC connected to the data signal line DLx so that the capacitance ratio related to the data signal line DLx matches the capacitance ratio related to the data signal line DLz, the change in electric potential ΔVx becomes substantially identical to the change in electric potential ΔVz. This makes it possible to suppress vertically striped luminance unevenness.

By causing the unit circuit Uc connected to the data signal line DLz to be smaller in size as illustrated in FIG. 15, each of the driving capability and the parasitic capacitance of each of the analog switches of the unit circuit Uc become lower. This makes it possible to effectively suppress vertically striped luminance unevenness.

### Embodiment 6

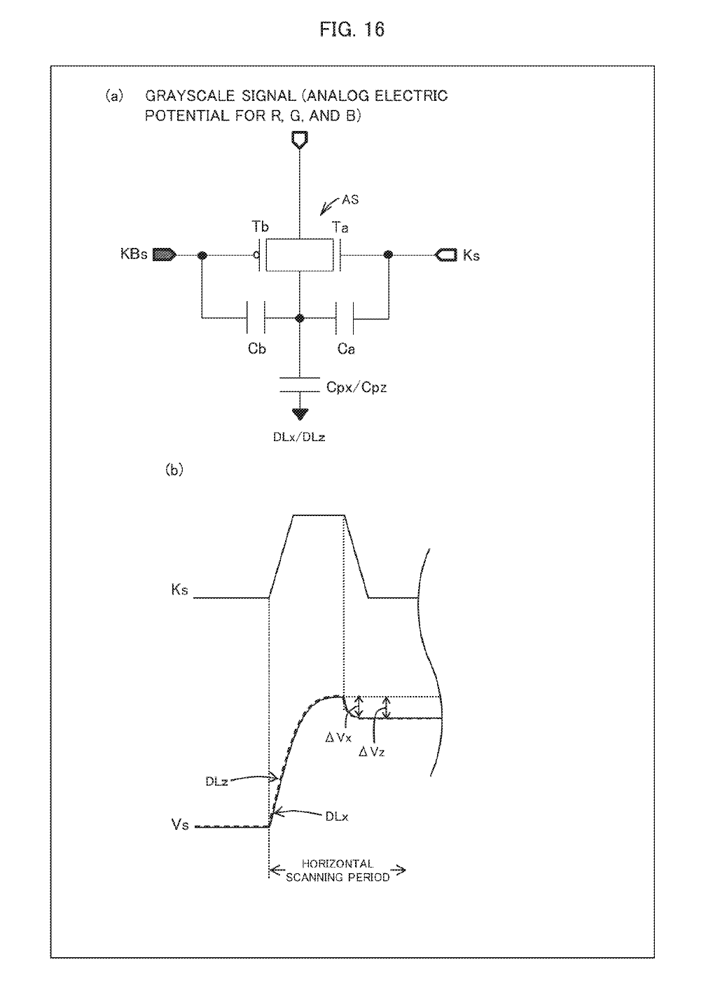

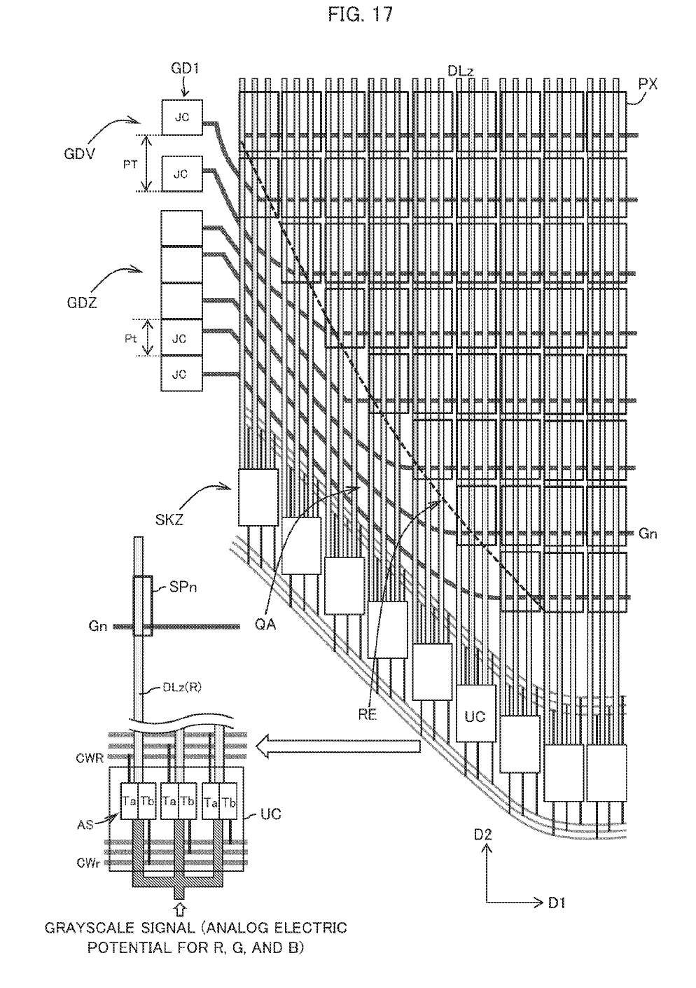

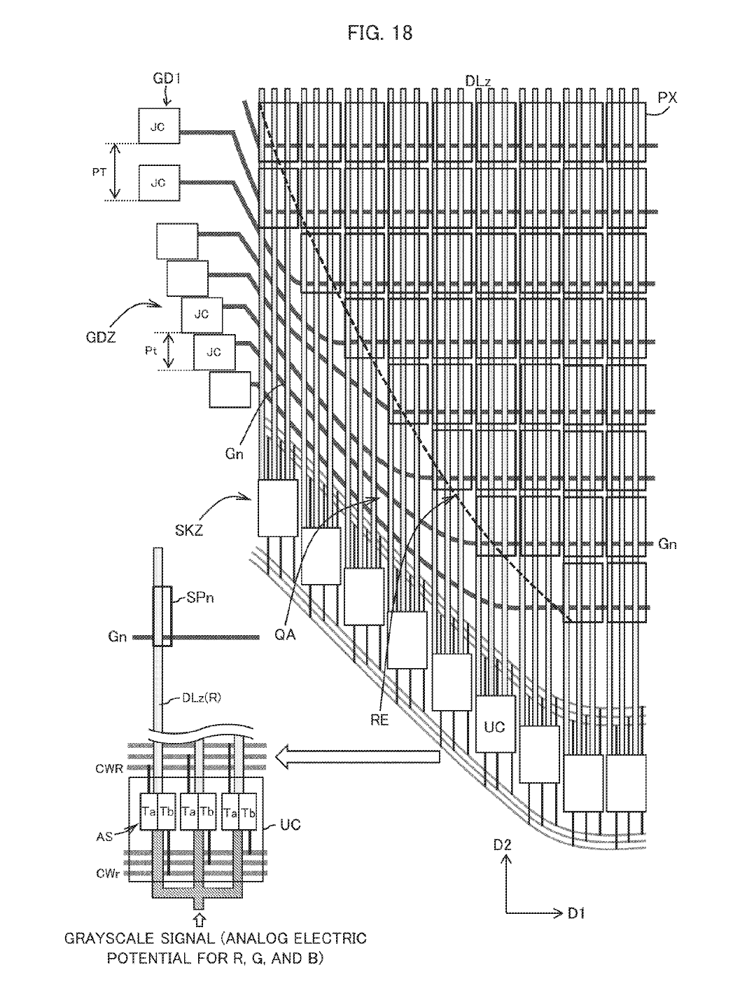

FIG. 17 is a plan view illustrating a configuration of a liquid crystal panel in accordance with Embodiment 6. As illustrated in FIG. 17, a gate driver GD1 can be constituted by a plurality of signal generating circuits JC (including flip flops and output circuits), and a pitch Pt between adjacent signal generating circuits JC in an end part GDZ of the gate driver GD1 can be shorter than a pitch PT between adjacent signal generating circuits JC in a non-end part GDV of the gate driver GD1. This allows an increase in degree of freedom of a panel layout. In this case, as illustrated in FIG. 18, the end part GDZ of the gate driver GD1 can be curved so as to extend along an irregularly-shaped edge RE.

[Recap]

A display device in accordance with an embodiment of the present invention is suitable for not only a liquid crystal display but also an OLED (Organic Light Emitting Diode) display, a QLED (Quantum dot Light Emitting Diode) display, and the like.

The present invention is not limited to the embodiments, but can be altered by a skilled person in the art within the scope of the claims. The present invention also encompasses, in its technical scope, any embodiment derived by combining technical means disclosed in differing embodiments. Further, it is possible to form a new technical feature by combining the technical means disclosed in the respective embodiments.

[Aspect 1]

A display panel including:

a display area;

sub pixels which are provided in the display area;

a driver which is located on an outer side of an edge of the display area;

a signal switching circuit which is located on the outer side of the edge of the display area; and

an mth scanning signal line and an nth scanning signal line each of which extends in a first direction in the display area,

the edge of the display area including an irregularly-shaped edge which is curved or oblique with respect to the first direction,

an end part of the signal switching circuit being located on an outer side of the irregularly-shaped edge,

the nth scanning signal line crossing the irregularly-shaped edge, passing through a space between the irregularly-shaped edge and the end part of the signal switching circuit, and being drawn to the driver, as viewed from above.

[Aspect 2]

The display panel as described in, for example, Aspect 1, wherein:

the edge of the display area includes a straight edge;

the mth scanning signal line crosses the straight edge, as viewed from above; and

the number of sub pixels connected to the nth scanning signal line is less than the number of sub pixels connected to the mth scanning signal line.

[Aspect 3]

The display panel as described in, for example, Aspect 2, wherein the nth scanning signal line is longer than the mth scanning signal line.

[Aspect 4]

The display panel as described in, for example, any one of Aspects 1 through 3, wherein the end part of the signal switching circuit is curved or oblique with respect to the first direction.

[Aspect 5]

The display panel as described in, for example, Aspect 4, wherein the end part of the signal switching circuit is shaped so that a distance between the end part of the signal switching circuit and the irregularly-shaped edge becomes longer toward a tip of the signal switching circuit.

[Aspect 6]

The display panel as described in, for example, Aspect 4, wherein:

the signal switching circuit is constituted by a plurality of unit circuits; and

a pitch between adjacent ones of the plurality of unit circuits which adjacent ones are included in the end part of the signal switching circuit is shorter than a pitch between other adjacent ones of the plurality of unit circuits which other adjacent ones are included in a non-end part of the signal switching circuit.

[Aspect 7]

The display panel as described in, for example, Aspect 4, wherein:

the signal switching circuit is constituted by a plurality of unit circuits; and

one of the plurality of unit circuits which one is included in the end part of the signal switching circuit is smaller, in size, than another one of the plurality of unit circuits which another one is included in a non-end part of the signal switching circuit.

[Aspect 8]

The display panel as described in, for example, any one of Aspects 1 through 7, further including:

a dummy sub pixel which is at least partially located on the outer side of the irregularly-shaped edge and which does not contribute to display; and

a data signal line which crosses the irregularly-shaped edge,

the dummy sub pixel being connected to the nth scanning signal line and the data signal line.

[Aspect 9]

The display panel as described in, for example, any one of Aspects 1 through 8, wherein an end part of the driver is shaped so as to extend along the irregularly-shaped edge.

[Aspect 10]

The display panel as described in, for example, any one of Aspects 1 through 9, wherein the driver is provided so as not to overlap with the end part of the signal switching circuit, as viewed in the first direction.

[Aspect 11]

The display panel as described in, for example, any one of Aspects 1 through 10, wherein:

the driver is constituted by a plurality of signal generating circuits; and

a pitch between adjacent ones of the plurality of signal generating circuits which adjacent ones are included in an end part of the driver is shorter than a pitch between other adjacent ones of the plurality of signal generating circuits which other adjacent ones are included in a non-end part of the driver.

### REFERENCE SIGNS LIST

2 Display device
LP Liquid crystal panel
GD1, GD2 Gate driver
SK Signal switching circuit
SPm, SPn Sub pixel
SPd Dummy sub pixel
Gm, Gn Scanning signal line
TR Transistor (of a sub pixel)
DA Display area
NA Non-display area
TE, Te Straight edge
RE, Re Irregularly-shaped edge
DLx, DLz Data signal line

1. A display panel comprising:
a display area;
sub pixels which are provided in the display area;
a driver which is located on an outer side of an edge of the display area;
a signal switching circuit which is located on the outer side of the edge of the display area; and
an mth scanning signal line and an nth scanning signal line each of which extends in a first direction in the display area,
m being a natural number,
n being a natural number other than m,
the edge of the display area including an irregularly-shaped edge which is curved or oblique with respect to the first direction,
an end part of the signal switching circuit being located on an outer side of the irregularly-shaped edge,
the nth scanning signal line crossing the irregularly-shaped edge, passing through a space between the irregularly-shaped edge and the end part of the signal switching circuit, and being drawn to the driver, as viewed from above.

2. The display panel as set forth in claim 1, wherein:
the edge of the display area includes a straight edge;
the mth scanning signal line crosses the straight edge, as viewed from above; and
the number of sub pixels connected to the nth scanning signal line is less than the number of sub pixels connected to the mth scanning signal line.

3. The display panel as set forth in claim 2, wherein the nth scanning signal line is longer than the mth scanning signal line.

4. The display panel as set forth in claim 1, wherein the end part of the signal switching circuit is curved or oblique with respect to the first direction.

5. The display panel as set forth in claim 4, wherein the end part of the signal switching circuit is shaped so that a distance between the end part of the signal switching circuit and the irregularly-shaped edge becomes longer toward a tip of the signal switching circuit.

6. The display panel as set forth in claim 4, wherein:
the signal switching circuit is constituted by a plurality of unit circuits; and
a pitch between adjacent ones of the plurality of unit circuits which adjacent ones are included in the end part of the signal switching circuit is shorter than a pitch between other adjacent ones of the plurality of unit circuits which other adjacent ones are included in a non-end part of the signal switching circuit.

7. The display panel as set forth in claim 4, wherein:
the signal switching circuit is constituted by a plurality of unit circuits; and
one of the plurality of unit circuits which one is included in the end part of the signal switching circuit is smaller, in size, than another one of the plurality of unit circuits which another one is included in a non-end part of the signal switching circuit.

8. The display panel as set forth in claim 1, further comprising:
a dummy sub pixel which is at least partially located on the outer side of the irregularly-shaped edge and which does not contribute to display; and
a data signal line which crosses the irregularly-shaped edge,
the dummy sub pixel being connected to the nth scanning signal line and the data signal line.

9. The display panel as set forth in claim 1, wherein an end part of the driver is shaped so as to extend along the irregularly-shaped edge.

10. The display panel as set forth in claim 1, wherein the driver is provided so as not to overlap with the end part of the signal switching circuit, as viewed in the first direction.

11. The display panel as set forth in claim 1, wherein:
the driver is constituted by a plurality of signal generating circuits; and
a pitch between adjacent ones of the plurality of signal generating circuits which adjacent ones are included in an end part of the driver is shorter than a pitch between other adjacent ones of the plurality of signal generating circuits which other adjacent ones are included in a non-end part of the driver.
